(19) United States
(12) Patent Application Publication
(10) Pub. No.: US 2024/0130198 A1
(43) Pub. Date: Apr. 18, 2024

(54) DISPLAY APPARATUS

(71) Applicant: Samsung Display Co., LTD., Yongin-si (KR)

(72) Inventors: Sangho HWANG, Yongin-si (KR); Heonjung SHIN, Yongin-si (KR)

(21) Appl. No.: 18/239,903

(22) Filed: Aug. 30, 2023

(30) Foreign Application Priority Data
Oct. 17, 2022 (KR) 10-2022-0133611

(51) Int. Cl. H10K 59/80; G06F 1/16; H04M 1/02

(52) U.S. Cl. CPC H10K 59/873; G06F 1/1616; G06F 1/1652; G06F 1/1656; H04M 1/0216; H04M 1/0268; H10K 2102/311

(57) ABSTRACT

A display apparatus includes a display panel including a foldable area, and a first non-foldable area and a second non-foldable area, a cover window disposed on the display panel, and a protective layer including a soft layer and a hard layer. The soft layer is on the cover window and includes a first material, and the hard layer is on the soft layer and includes a second material having a Young's modulus greater than a Young's modulus of the first material, where the soft layer includes a hard pattern in a portion overlapping the first non-foldable area and the second non-foldable area, and the hard pattern is not in a portion overlapping the foldable area.

This application claims priority to Korean Patent Application No. 10-2022-0133611, filed on Oct. 17, 2022, and all the benefits accruing therefrom under 35 U.S.C. § 119, the content of which in its entirety is herein incorporated by reference.

### BACKGROUND

### 1. Field

One or more embodiments relate to a protective layer and a display apparatus including the protective layer. In particular, one or more embodiments relate to foldable display apparatus that is foldable or bendable and includes the protective layer.

### 2. Description of the Related Art

Electronic apparatuses based on mobility or portable electronic apparatuses are widely used. As mobile or portable electronic apparatuses, tablet personal computers (PCs) have been broadly used, in addition to small electronic apparatuses, such as mobile phones.

Such a mobile electronic apparatuses include a display apparatus to provide a display function, e.g., to provide a user with visual information such as an image. Recently, methods of expanding a display area of a display apparatus and simultaneously adding various functions to the display area have been studied.

In addition, a display apparatus in which a portion thereof is folded or rolled has been developed to reduce the overall size of an electronic apparatus and increase the area of a display area.

### SUMMARY

One or more embodiments provide a protective layer arranged over a display panel. However, the embodiments are examples, and do not limit the scope of the disclosure.

According to one or more embodiments, a display apparatus includes a display panel including a foldable area, and a first non-foldable area and a second non-foldable area, where the foldable area is foldable about an axis extending in a first direction, and the first non-foldable area and the second non-foldable area are spaced apart from each other in a second direction crossing the first direction with the foldable area therebetween, a cover window disposed on the display panel, and a protective layer disposed on the cover window, where the protective layer includes a soft layer and a hard layer, the soft layer is on the cover window and includes a first material, and the hard layer is on the soft layer and includes a second material having a Young's modulus greater than a Young's modulus of the first material, where the soft layer includes a hard pattern in a portion overlapping the first non-foldable area and the second non-foldable area, and the hard pattern is not in a portion overlapping the foldable area.

According to an embodiment, the first material may have a Young's modulus less than a Young's modulus of the hard pattern.

According to an embodiment, the Young's modulus of the first material may be in a range of about 700 megapascals (MPa) to about 900 MPa.

According to an embodiment, the hard pattern may include a plurality of unit patterns, each of the plurality of unit patterns of the hard pattern may have a first width in the first direction and a second width in the second direction, the first width may be in a range of about 100 micrometers (μm) to about 300 μm, and the second width may be in a range of about 100 μm to about 300 μm.

According to an embodiment, the first width and the second width may be equal to each other.

According to an embodiment, the first width and the second width may be different from each other.

According to an embodiment, a thickness of the soft layer may be less than a thickness of the hard layer.

According to an embodiment, the hard pattern may include a plurality of unit patterns, and each of the plurality of unit patterns may have at least one selected from a honeycomb shape, a triangular shape, a rectangular shape, and a circular shape.

According to an embodiment, the hard pattern may include an ultraviolet (UV) curable resin.

According to an embodiment, the first material may include a UV curable resin.

According to an embodiment, the hard pattern may include a material different from the second material.

According to an embodiment, the hard pattern may have a Young's modulus in a range of about 3 gigapascals (GPa) to about 6 GPa.

According to an embodiment, the second material may include at least one selected from polyethylene terephthalate (PET), polyimide (PI), polyethersulfone (PS), polyacrylate (PAR), polyetherimide (PEI), polyethylene naphthalate (PEN), polyethylene sulfide (PPS), and polycarbonate (PC).

According to one or more embodiments, a display apparatus includes a display panel including a foldable area, and a first non-foldable area and a second non-foldable area, where the foldable area is foldable about an axis extending in a first direction, and the first non-foldable area and the second non-foldable area being spaced apart from each other in a second direction crossing the first direction with the foldable area therebetween, a cover window disposed on the display panel, and a protective layer disposed on the cover window, where the protective layer includes a soft layer on the cover window and a hard layer on the soft layer, where the soft layer includes a hard pattern and a first material, the hard pattern is arranged to overlap the first non-foldable area and the second non-foldable area, and the first material has a Young's modulus in a range of about 700 MPa to about 900 MPa and disposed in a space defined by the hard pattern, and the hard layer includes a second material having a Young's modulus greater than the Young's modulus of the first material.

According to an embodiment, the hard pattern may not be in a portion of the soft layer overlapping the foldable area, and the hard pattern may have a Young's modulus greater than the Young's modulus of the first material.

According to an embodiment, the hard pattern may include a plurality of unit patterns, each of the plurality of unit patterns may have a first width in the first direction and a second width in the second direction crossing the first direction, the first width may be in a range of about 100 μm to about 300 μm, and the second width may be in a range of about 100 μm to about 300 μm.

According to an embodiment, a thickness of the soft layer may be less than a thickness of the hard layer.

According to an embodiment, the hard pattern may include a plurality of unit patterns, and each of the plurality of unit patterns may have at least one selected from a honeycomb shape, a triangular shape, a rectangular shape, and a circular shape.

According to an embodiment, the hard pattern may include a UV curable resin.

According to an embodiment, the first material may include a UV curable resin.

### BRIEF DESCRIPTION OF THE DRAWINGS

The above and other features of certain embodiments of the disclosure will be more apparent from the following description taken in conjunction with the accompanying drawings, in which:

FIGS. 1A and 1B are schematic diagrams of a display apparatus before being folded, according to embodiments;

FIGS. 2A and 2B are schematic diagrams of a display apparatus in a folded state, according to an embodiment;

FIG. 3 is an equivalent circuit diagram of an embodiment of a pixel circuit included in a display apparatus, according to an embodiment;

FIG. 4 is a schematic cross-sectional view of an area of a display apparatus, taken along line I-I′ of FIG. 1, according to an embodiment;

FIG. 5 is a schematic cross-sectional view of a display apparatus, taken along line II-II′ of FIG. 1A, according to an embodiment;

FIGS. 6A to 6D are schematic plan views of a soft layer, according to embodiments;

FIG. 7 is a table showing strain and impact resistance of a display panel according to a layer configuration of a protective layer;

FIG. 8 is a table showing strain of a display panel according to a modulus of a material included in a soft layer of a protective layer; and

FIG. 9 is a table showing strain of a display panel according to a width of a hard pattern included in a soft layer of a protective layer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As used herein, the term “and/or” includes any and all combinations of one or more of the associated listed items. Throughout the disclosure, the expression “at least one of a, b or c”, “at least one of a, b and c” or “at least one selected from a, b and c” indicates only a, only b, only c, both a and b, both a and c, both b and c, all of a, b, and c, or variations thereof.

As various modifications may be applied and numerous embodiments may be implemented, particular embodiments will be illustrated in the drawings and described in detail in the written description. Effects and features, and methods for achieving them will be clarified with reference to embodiments described below in detail with reference to the drawings. However, the embodiments may have different forms and should not be construed as being limited to the descriptions set forth herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being connected to another layer, region, or element, it can be directly or indirectly connected to the other layer, region, or element. That is, for example, intervening layers, regions, or elements may be present. For example, it will be understood that when a layer, region, or element is referred to as being “electrically connected to” or “electrically coupled to” another layer, region, and element, it may be directly or indirectly electrically connected or coupled to the other layer, region, or element. That is, e.g., intervening layers, regions, or elements may be present.

It will be further understood that, when a layer, region, or element is referred to as being “on” another layer, region, or element, it can be directly or indirectly on the other layer, region, or element. That is, e.g., intervening layers, regions, or elements may be present.

Sizes of elements in the drawings may be exaggerated for convenience of description. For example, because sizes and thicknesses of elements in the drawings are arbitrarily illustrated for convenience of description, the embodiments are not limited thereto.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, the embodiments will now be described in detail with reference to the accompanying drawings. When described with reference to the drawings, identical or corresponding elements will be given the same reference numerals, and any repetitive detailed description thereof will be omitted or simplified.

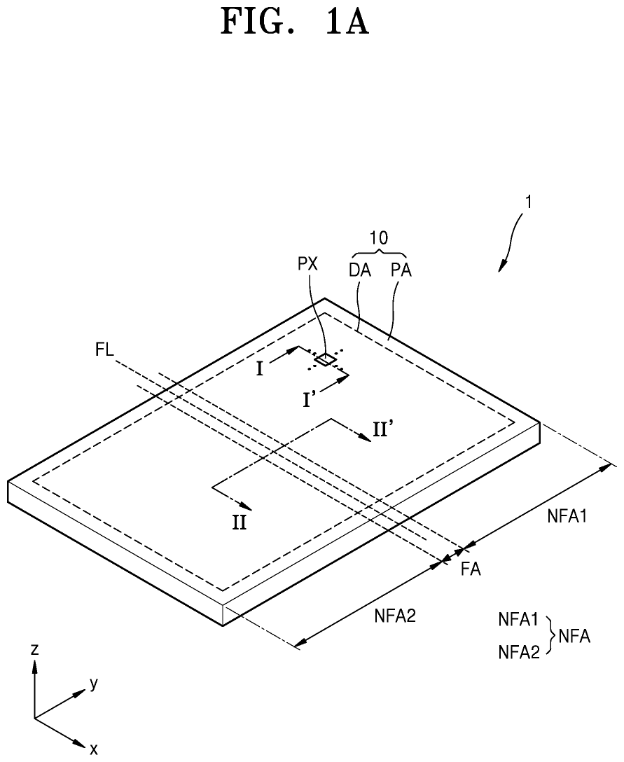

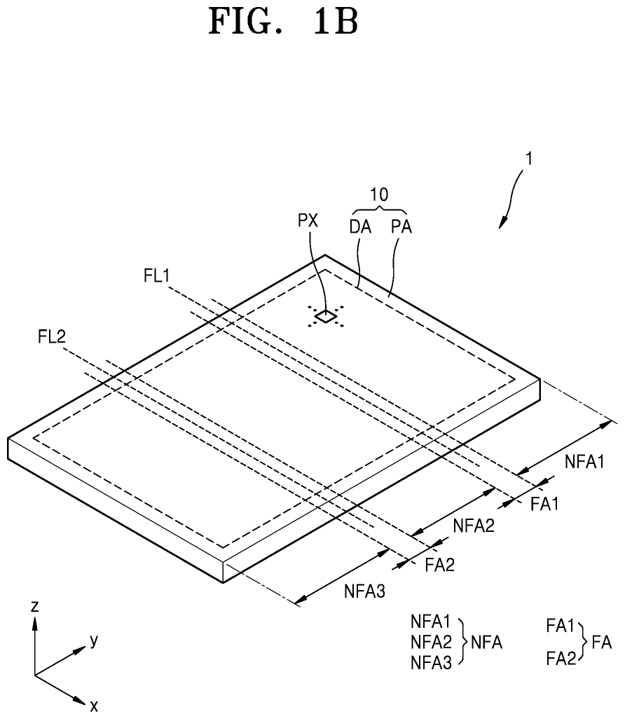

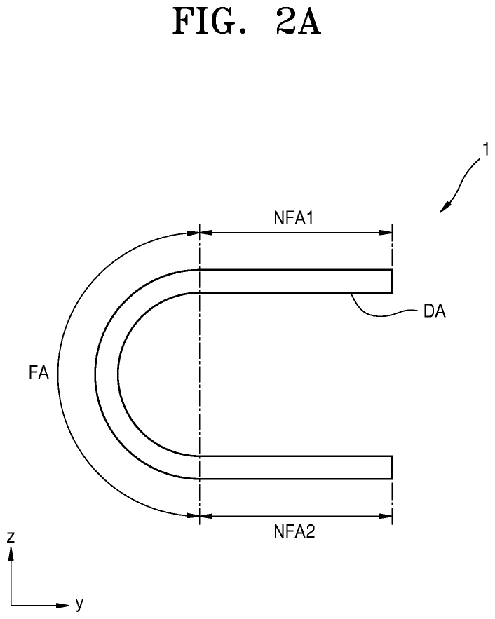

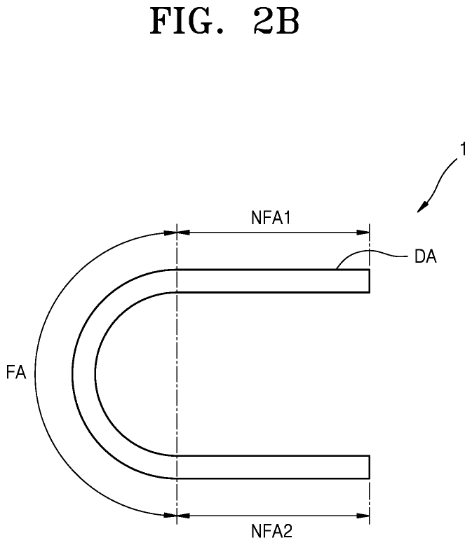

FIGS. 1A and 1B are schematic diagrams of a display apparatus 1 before being folded, according to embodiments. FIGS. 2A and 2B are schematic cross-sectional views of the display apparatus 1 in a folded state, according to an embodiment.

According to an embodiment, an embodiment of the display apparatus 1 may include a foldable or bendable display apparatus 1. The display apparatus 1 may be provided in various shapes, e.g., may be provided in a rectangular plate shape in which two pairs of sides are parallel to each other. In an embodiment where the display apparatus 1 is provided in a rectangular plate shape, any one pair of the two pairs of sides may be provided longer than the other pair of sides. In FIGS. 1A and 1B, for convenience of illustration and description, an embodiment in which the display apparatus 1 has a rectangular shape having a pair of long sides and a pair of short sides is shown, an extension direction of the short sides is indicated as a first direction (x-axis direction), an extension direction of the long side is indicated as a second direction (y-axis direction), and a direction perpendicular to the extension directions of the long sides and the short sides (or a thickness direction of the display apparatus 1) is indicated as a third direction (z-axis direction).

According to an embodiment, the shape of the display apparatus 1 is not limited to the aforementioned shapes and may have various shapes. In an embodiment, for example, the display apparatus 1 may be provided in various shapes, such as a closed polygonal shape including straight sides, a circular or elliptical shape including curved sides, a semicircular shape or half-elliptical shape including straight and curved sides, or the like. According to an embodiment, where the display apparatus 1 has straight sides, at least some of corners of each shape of the display apparatus 1 may be curved. In an embodiment, for example, when the display apparatus 1 has a rectangular shape, a portion of the display apparatus 1 where straight sides adjacent to each other meet may be replaced with a curve having a certain curvature. That is, a vertex portion of a rectangular shape may be formed as a curved side having a certain curvature and having both ends adjacent to each other connected to two adjacent straight sides. In such an embodiment, the curvature may be differently set according to a position of the curve. In an embodiment, for example, the curvature may be changed according to a starting position of the curve and a length of the curve.

Referring to FIGS. 1A, 1B, 2A, and 2B, an embodiment of the display apparatus 1 may include a display panel 10. The display panel 10 may include a display area DA and a peripheral area PA outside the display area DA. The display area DA may be an area in which a plurality of pixels PX are arranged to display an image. The peripheral area PA may be a non-display area surrounding the display area DA and in which pixels are not arranged.

Various electronic apparatuses, printed circuit boards, etc. may be electrically attached to the peripheral area PA, and a voltage line configured to supply power for driving display elements, etc. may be positioned in the peripheral area PA. In an embodiment, for example, a scan driver configured to provide a scan signal to each pixel PX, a data driver configured to provide a data signal to each pixel PX, a supply line (a clock signal line, a carry signal line, a driving voltage line, or the like) of a signal input to the scan driver and the data driver, a main power line, etc. may be arranged in the peripheral area PA.

At least a portion of the display panel 10 may be flexible, and the flexible portion may be folded. That is, the display panel 10 may include a foldable area FA that is flexible and foldable, and a non-foldable area NFA that is provided on at least one side of the foldable area and not folded. In an embodiment, an area that is not folded is referred to as a non-foldable area, for convenience of description. The term “non-foldable” includes not only a case in which the area is hard due to no flexibility, but also a case in which the area is flexible but less flexible than the foldable area FA, and a case in which the area is flexible but not folded. The display panel 10 may display an image in the display area DA of the foldable area FA and the non-foldable area NFA.

For convenience of illustration and description, FIG. 1A illustrates an embodiment where two non-foldable areas NFA1 and NFA2 have similar areas to each other, and one foldable area FA is between the two non-foldable areas NFA1 and NFA2, but one or more embodiments are not limited thereto. In an alternative embodiment, for example, the non-foldable areas NFA1 and NFA2 may have different areas from each other.

In an alternative embodiment, as shown in FIG. 1B, one or more foldable areas FA may be provided. In such an embodiment, a plurality of non-foldable areas NFA1, NFA2, and NFA3 may be spaced apart from each other with foldable areas FA1 and FA2 therebetween. FIG. 1B illustrates an embodiment where the display panel 10 includes three non-foldable areas NFA1, NFA2, and NFA3, and two foldable areas FA1 and FA2 are between the non-foldable areas NFA1, NFA2, and NFA3, but one or more embodiments are not limited thereto. That is, the number of non-foldable areas NFA and the number of foldable areas FA may be variously changed depending on the embodiments.

Respective foldable areas FA, FA1, and FA2 may be folded (or foldable) based on folding lines (or folding axes) FL, FL1, and FL2 extending in the first direction (x-axis direction), and the folding lines FL, FL1, and FL2 may be provided in plural. The folding lines FL, FL1, and FL2 are provided in the foldable areas FA, FA1, and FA2 in the second direction (y-axis direction), which is an extension direction of the foldable areas FA, FA1, and FA2, and accordingly, the display panel 10 may be folded in the foldable areas FA, FA1, and FA2. The non-foldable areas NFA1, NFA2, and NFA3 may be spaced apart from each other in the second direction (y-axis direction), which crosses the first direction (x-axis direction), with the foldable areas FA, FA1, and FA2 therebetween. In an embodiment, as shown in FIG. 1A, the non-foldable area NFA may include the first non-foldable area NFA1 and the second non-foldable area NFA2, which are spaced apart from each other in the second direction (y-axis direction) with the foldable area FA therebetween. In an alternative embodiment, as shown in FIG. 1B, the non-foldable area NFA may include the first non-foldable area NFA1, the second non-foldable area NFA2, and the third non-foldable area NFA3, which are spaced apart from each other in the second direction (y-axis direction) with the foldable areas FA1 and FA2 therebetween.

FIGS. 1A and 1B illustrate an embodiment where the folding lines FL, FL1, and FL2 cross the center of the foldable areas FA, FA1, and FA2, and the foldable areas FA, FA1, and FA2 are axisymmetric with respect to the folding lines FL, FL1, and FL2, but are not limited thereto. Alternatively, the folding lines FL, FL1, and FL2 may be asymmetrically provided within the foldable areas FA, FA1, and FA2. The foldable areas FA, FA1, and FA2 and the folding lines FL, FL1, and FL2 in the foldable areas FA, FA1, and FA2 may overlap an area of the display panel 10, in which an image is displayed, and when the display panel 10 is folded, the area in which an image is displayed may be folded.

In an alternative embodiment, the display panel 10 may entirely correspond to a foldable area. In an embodiment, for example, where a display apparatus that rolls like a scroll, the display panel 10 may entirely correspond to a foldable area.

As shown in FIGS. 1A and 1B, an embodiment, the display panel 10 may be entirely unfolded to be in a flat state. In an embodiment, as shown in FIG. 2A, the display panel 10 may be folded so that portions of the display area DA face each other with respect to the folding line FL. In an alternative embodiment, as shown in FIG. 2B, the display panel 10 may be folded so that the display area DA faces outward with respect to the folding line FL. In this case, the term “folded” means that the shape is not fixed, but an original shape may be transformed into another shape, and includes being folded, curved, or rolled along one or more specific lines, i.e., folding lines FL. Accordingly, according to an embodiment, one surface of each of the two non-foldable areas NFA1 and NFA2 are positioned parallel to each other and folded to face each other, but are not limited thereto. Surfaces of the two non-foldable areas NFA1 and NFA2 may be folded at a certain angle (e.g., an acute angle, a right angle, or an obtuse angle) with the foldable area FA therebetween.

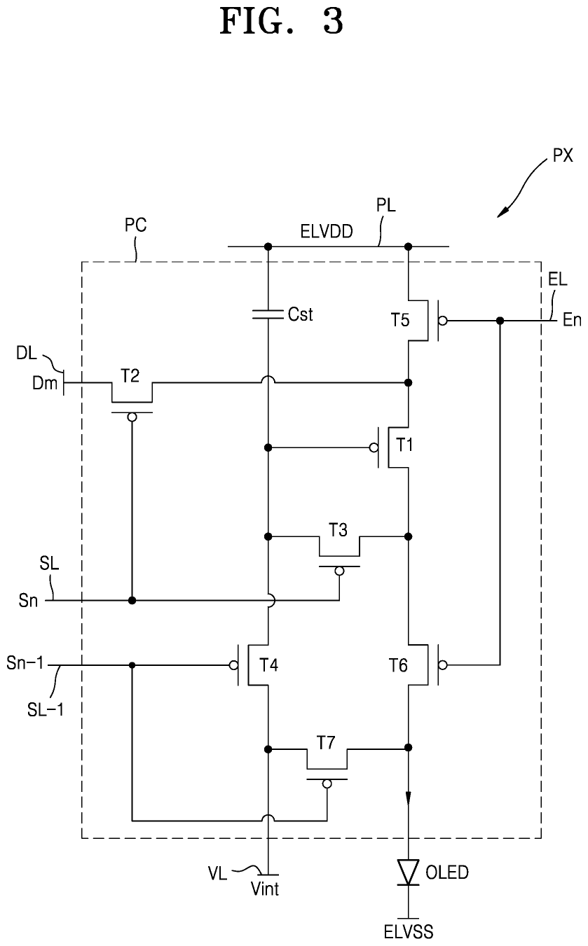

FIG. 3 is an equivalent circuit diagram of an embodiment of a pixel circuit PC included in the display apparatus 1 of FIGS. 1A and 1B. FIG. 3 is an equivalent circuit diagram of the pixel circuit PC electrically connected to an organic light-emitting diode OLED constituting some pixels PX included in the display apparatus 1 of FIGS. 1A and 1B.

Referring to FIG. 3, in an embodiment, the pixel circuit PC may include a driving thin-film transistor T1 and a plurality of switching thin-film transistors. The switching thin-film transistors may include a data write thin-film transistor T2, a compensation thin-film transistor T3, a first initialization thin-film transistor T4, an operation control thin-film transistor T5, an emission control thin-film transistor T6, and a second initialization thin-film transistor T7.

FIG. 3 illustrates an embodiment in which a scan line SL, a previous scan line SL-1, an emission control line EL, a data line DL, an initialization voltage line VL, and a driving voltage line PL are provided for each pixel circuit PC. However, in an alternative embodiment, at least one of the scan line SL, the previous scan line SL-1, the emission control line EL, the data line DL, and initialization voltage line VL, and/or the initialization voltage line VL may be shared by neighboring pixel circuits.

A drain electrode of the driving thin-film transistor T1 may be electrically connected to the organic light-emitting diode OLED via the emission control thin-film transistor T6. The driving thin-film transistor T1 may be configured to receive a data signal Dm and supply a driving current to the organic light-emitting diode OLED in response to a switching operation of the data write thin-film transistor T2.

A gate electrode of the data write thin-film transistor T2 may be connected to the scan line SL, and a source electrode thereof may be connected to the data line DL. A drain electrode of the data write thin-film transistor T2 may be connected to the source electrode of the driving thin-film transistor T1 and connected to the driving voltage line PL via the operation control thin-film transistor T5.

The data write thin-film transistor T2 may be turned on in response to a scan signal Sn received through the scan line SL and may be configured to perform a switching operation of transmitting the data signal Dm to the source electrode of the driving thin-film transistor T1 through the data line DL.

A gate electrode of the compensation thin-film transistor T3 may be connected to the scan line SL. A source electrode of the compensation thin-film transistor T3 may be connected to the drain electrode of the driving thin-film transistor T1 and connected to a pixel electrode of the organic light-emitting diode OLED via the emission control thin-film transistor T6. A drain electrode of the compensation thin-film transistor T3 may be connected to one of the electrodes of a storage capacitor Cst, a source electrode of the first initialization thin-film transistor T4, and the gate electrode of the driving thin-film transistor T1. The compensation thin-film transistor T3 may be turned on in response to the scan signal Sn received through the scan line SL and may be configured to connect the gate electrode to the drain electrode of the driving thin-film transistor T1, such that the driving thin-film transistor T1 is diode-connected.

A gate electrode of the first initialization thin-film transistor T4 may be connected to the previous scan line SL-1. A drain electrode of the first initialization thin-film transistor T4 may be connected to the initialization voltage line VL. A source electrode of the first initialization thin-film transistor T4 may be connected to one of the electrodes of the storage capacitor Cst, the drain electrode of the compensation thin-film transistor T3, and the gate electrode of the driving thin-film transistor T1. The first initialization thin-film transistor T4 may be turned on in response to a previous scan signal Sn-1 received through the previous scan line SL-1 and may be configured to transmit an initialization voltage Vint to the gate electrode of the driving thin-film transistor T1 and perform an initialization operation of initializing a voltage of the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the data write thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the organic light-emitting diode OLED. The operation control thin-film transistor T5 and the emission control thin-film transistor T6 are simultaneously turned on in response to an emission control signal En received through the emission control line EL, a first power voltage ELVDD is transmitted to the organic light-emitting diode OLED, and the driving current flows through the organic light-emitting diode OLED.

A gate electrode of the second initialization thin-film transistor T7 may be connected to the previous scan line SL-1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on in response to the previous scan signal Sn-1 received through the previous scan line SL-1 and may be configured to initialize the pixel electrode of the organic light-emitting diode OLED.

FIG. 3 illustrates an embodiment in which both the first initialization thin-film transistor T4 and the second initialization thin-film transistor T7 are connected to the previous scan line SL-1. However, in an alternative embodiment, each of the first initialization thin-film transistor T4 and the second initialization thin-film transistor T7 may be connected to the previous scan line SL-1 and a next scan line (not shown), and each of the first initialization thin-film transistor T4 and the second initialization thin-film transistor T7 may be driven in response to the previous scan signal Sn-1 and a next scan signal.

One of the electrodes of the storage capacitor Cst may be connected to the driving voltage line PL. The other of the electrodes of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode or a common electrode) of the organic light-emitting diode OLED may receive a second power voltage ELVSS. The organic light-emitting diode OLED may emit light by receiving the driving current from the driving thin-film transistor T1.

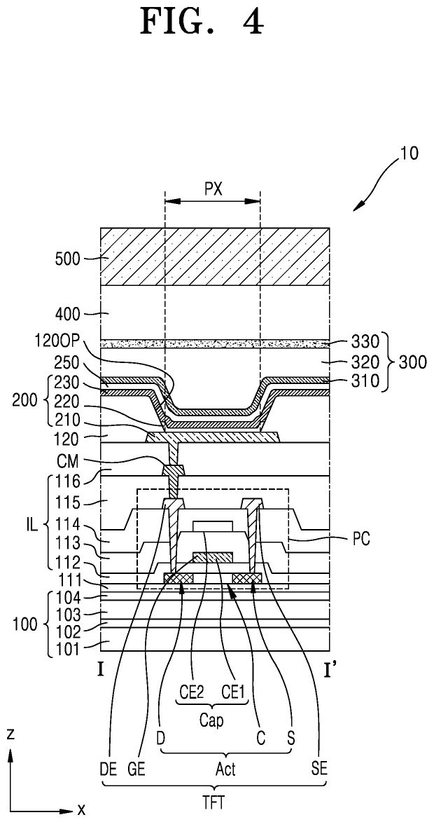

FIG. 4 is a schematic cross-sectional view of an area of a display panel 10 provided in a display apparatus, according to an embodiment, and may correspond to a cross-section of the display panel 10, taken along line I-I′ of FIG. 1A.

Referring to FIG. 4, an embodiment of the display panel 10 may include a substrate 100. In an embodiment, the substrate 100 may have a multi-layered structure including an inorganic layer and a base layer including a polymer resin. In an embodiment, for example, the substrate 100 may include a first base layer 101, a first barrier layer 102, a second base layer 103, and a second barrier layer 104, which are sequentially stacked one on another. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP). Each of the first barrier layer 102 and the second barrier layer 104 may include an inorganic insulating material, such as silicon oxide, silicon oxynitride, and/or silicon nitride. The substrate 100 may be flexible.

A buffer layer 111 may be disposed on the substrate 100. The buffer layer 111 may reduce or block penetration of a foreign material, moisture, or external air from the bottom of the substrate 100 and may provide a flat surface on the substrate 100. The buffer layer 111 may include an inorganic insulating material, such as silicon oxide, silicon oxynitride, or silicon nitride, and may have a single-layered or multi-layered structure, each layer therein including at least one selected from the above materials.

The pixel circuit PC may be disposed on the buffer layer 111. The pixel circuit PC may include thin-film transistors TFT and a storage capacitor Cap.

A thin-film transistor TFT of the pixel circuit PC may include a semiconductor layer Act, a gate electrode GE overlapping a channel region of the semiconductor layer Act, and a source electrode SE and a drain electrode DE respectively connected to a source region S and a drain region D of the semiconductor layer Act.

In an embodiment, the semiconductor layer Act on the buffer layer 111 may include polysilicon. Alternatively, the semiconductor layer Act may include amorphous silicon, may include an oxide semiconductor, or may include an organic semiconductor or the like. The semiconductor layer Act may include a channel region C and a drain region D and a source region S, which are disposed on opposing sides of the channel region C. The drain region D and the source region S may be regions doped with impurities.

The gate electrode GE may include a low-resistance metal material. The gate electrode GE may include a conductive material including molybdenum (Mo), aluminum (Al), copper (Cu), and titanium (Ti) and may have a single layer or multi-layer including at least one selected from the above materials.

A first gate insulating layer 112 may be between the semiconductor layer Act and the gate electrode GE. The first gate insulating layer 112 may include, e.g., an inorganic insulating material, such as silicon oxide (SiO₂), SiNₓ, silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A second gate insulating layer 113 may cover the gate electrode GE. Similar to the first gate insulating layer 112, the second gate insulating layer 113 may include an inorganic insulating material, such as SiO₂, SiNₓ, SiON, Al₂O₃, TiO₂, Ta₂O₅, HfO₂, or ZnO₂.

In an embodiment, the storage capacitor Cap may overlap the thin-film transistor TFT. The storage capacitor Cap may include a first electrode CE1 and a second electrode CE2, which overlap each other. In some embodiments, the gate electrode GE of the thin-film transistor TFT may include the first electrode CE1 of the storage capacitor Cap.

The second electrode CE2 of the storage capacitor Cap may be disposed on the second gate insulating layer 113. The second electrode CE2 may overlap the gate electrode GE thereunder. In such an embodiment, the gate electrode GE and the second electrode CE2, which overlap each other with the second gate insulating layer 113 therebetween, may form the storage capacitor Cap. That is, the gate electrode GE overlapping the second electrode CE2 may function as the first electrode CE1 of the storage capacitor Cap. In an alternative embodiment, the storage capacitor Cap may also be provided not to overlap the thin-film transistor TFT.

The second electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may have a single-layered or multi-layered structure, each layer therein including at least one selected from the above materials.

An interlayer insulating layer 114 may cover the second electrode CE2. The interlayer insulating layer 114 may include SiO₂, SiNₓ, SiON, Al₂O₃, TiO₂, Ta₂O₅, HfO₂, or ZnO₂. The interlayer insulating layer 114 may have a single-layered or multi-layered structure, each layer therein including at least one selected from the above inorganic insulating materials.

The drain electrode DE and the source electrode SE may be disposed on the interlayer insulating layer 114. The drain electrode DE and the source electrode SE may be respectively connected to the drain region D and the source region S through contact holes defined in insulating layers thereunder. Each of the drain electrode DE and the source electrode SE may include a material having high conductivity. Each of the drain electrode DE and the source electrode SE may include a conductive material including Mo, Al, Cu, and Ti and may a single-layered or multi-layered structure, each layer therein including at least one selected from the above materials. In an embodiment, each of the drain electrode DE and the source electrode SE may have a multi-layered structure of Ti/Al/Ti.

A first planarization insulating layer 115 may cover the drain electrode DE and the source electrode SE. The first planarization insulating layer 115 may include an organic insulating material, such as a general-purpose polymer including polymethylmethacrylate (PMMA) or polystyrene (PS), polymer derivatives having a phenol-based group, an acrylic polymer, an imide-based polymer, an aryl ether-based polymer, an amide-based polymer, a fluorine-based polymer, a p-xylene-based polymer, a vinyl alcohol-based polymer, or a blend thereof.

The second planarization insulating layer 116 may be arranged on the first planarization insulating layer 115. A second planarization insulating layer 116 may include a same material as that of the first planarization insulating layer 115 and may include an organic insulating material, such as a general-purpose polymer including PMMA or PS, polymer derivatives having a phenol-based group, an acrylic polymer, an imide-based polymer, an aryl ether-based polymer, an amide-based polymer, a fluorine-based polymer, a p-xylene-based polymer, a vinyl alcohol-based polymer, or a blend thereof.

A light-emitting device 200 may be disposed on the second planarization insulating layer 116. In an embodiment, the light-emitting device 200 is an organic light-emitting diode (OLED) and may have a stacked structure including a pixel electrode 210, an opposite electrode 230 disposed on the pixel electrode 210, and an intermediate layer 220 between the pixel electrode 210 and the opposite electrode 230. The light-emitting device 200 may emit light through an emission area and may emit, e.g., red, green or blue light. In an embodiment, the emission area may be defined as a pixel PX.

The pixel electrode 210 may be arranged on the second planarization insulating layer 116. The pixel electrode 210 may be connected to a contact metal CM on the first planarization insulating layer 115 through a contact hole defined in the second planarization insulating layer 116. The contact metal CM may be electrically connected to the thin-film transistor TFT of the pixel circuit PC through a contact hole defined in the first planarization insulating layer 115. Accordingly, the pixel electrode 210 may be electrically connected to the pixel circuit PC through the contact metal CM and may be configured to receive the driving current from the pixel circuit PC.

In an embodiment, the pixel electrode 210 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). In an alternative embodiment, the pixel electrode 210 may include a reflection layer including Ag, Mg, Al, Pt, Pd, Au, Ni, Nd, Ir, Cr, or any compound thereof. In another alternative embodiment, the pixel electrode 210 may further include a layer including ITO, IZO, ZnO, or In₂O₃ on/under the reflection layer described above. In another alternative embodiment, the pixel electrode 210 may have a three-layered structure of ITO layer/Ag layer/ITO layer that are sequentially stacked.

A pixel-defining layer 120 may be disposed on the pixel electrode 210. The pixel-defining layer 120 may be provided with an opening 1200P covering an edge of the pixel electrode 210 and overlapping a central portion of the pixel electrode 210. The opening 1200P may define an emission area of light emitted from the organic light-emitting diode OLED. A size and/or a width of the opening 1200P may correspond to a size and/or a width of the emission area. Accordingly, a size and/or a width of the pixel PX may depend on the size and/or the width of the opening 1200P of the pixel-defining layer 120 corresponding thereto.

The pixel-defining layer 120 may prevent an arc or the like from being generated at the edge of the pixel electrode 210 by increasing a distance between the edge of the pixel electrode 210 and the opposite electrode 230 over the pixel electrode 210. The pixel-defining layer 120 may be formed through spin coating or the like by using an organic insulating material, such as PI, polyamide, an acrylic resin, benzocyclobutene, hexamethyldisiloxane (HMDSO), or a phenolic resin.

The intermediate layer 220 may include an emission layer arranged to overlap the pixel electrode 210. The emission layer may include a polymer organic material or a low molecular weight organic material that emits light having a certain color. Alternatively, the emission layer may include an inorganic light-emitting material or quantum dots. In an embodiment, the intermediate layer 220 may include a first functional layer (not shown) and a second functional layer (not shown) under and on the emission layer, respectively. The first functional layer is an element arranged under the emission layer and may include, e.g., a hole transport layer (HTL), or may include an HTL and a hole injection layer (HIL). The second functional layer is an element arranged on the emission layer and may include an electron transport layer (ETL) and/or an electron injection layer (EIL). Like the opposite electrode 230 to be described below, the first functional layer and/or the second functional layer may be a common layer entirely covering the substrate 100.

The opposite electrode 230 may be disposed on the pixel electrode 210 and overlap the pixel electrode 210. The opposite electrode 230 may include a conductive material having a small work function. In an embodiment, for example, the opposite electrode 230 may include a (semi-)transparent layer including Ag, Mg, Al, Pt, Pd, Au, Ni, Nd, Ir, Cr, lithium (Li), Ca, or an alloy thereof. Alternatively, the opposite electrode 230 may further include a layer including ITO, IZO, ZnO, or In₂O₃ on the (semi-)transparent layer including at least one selected from the above materials. In an embodiment, for example, the opposite electrode 230 may integrally formed as a single body to entirely cover the display area DA (refer to FIG. 2).

According to an embodiment, a capping layer 250 may be disposed on light-emitting devices 200. The capping layer 250 may include an inorganic insulating material, such as SiNₓ, and/or may include an organic insulating material. In an embodiment where the capping layer 250 includes an organic insulating material, the capping layer 250 may include, e.g., an organic insulating material, such as a triamine derivative, a carbazole biphenyl derivative, an arylene diamine derivative, tris(8-hydroxyquinoline) aluminum (Alq3), acryl, PI, or polyamide.

An encapsulation layer 300 may be disposed on the capping layer 250. The encapsulation layer 300 may overlap the light-emitting device 200. In an embodiment, as described above, the encapsulation layer 300 includes at least one inorganic encapsulation layer and at least one organic encapsulation layer. In an embodiment, as shown in FIG. 3, the encapsulation layer 300 has a stacked structure of a first inorganic encapsulation layer 310, an organic encapsulation layer 320, and a second inorganic encapsulation layer 330.

The first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy-based resin, PI, or polyethylene. In an embodiment, the organic encapsulation layer 320 may include acrylate. The organic encapsulation layer 320 may be formed by hardening a monomer or coating a polymer. The organic encapsulation layer 320 may have transparency.

A touch sensing layer 400 including sensing electrodes and trace lines electrically connected to the sensing electrodes may be disposed on the encapsulation layer 300. The touch sensing layer 400 may obtain coordinate information according to an external input, e.g., a touch event. The touch sensing layer 400 may sense an external input by a self-capacitance method or a mutual capacitance method.

An optical functional layer 500 may be disposed on the touch sensing layer 400. The optical functional layer 500 may reduce reflectance of light (external light) incident from the outside toward the display panel 10 and/or may improve the color purity of light emitted from the display panel 10.

In an embodiment, the optical functional layer 500 may include a retarder and/or a polarizer. The retarder may include a film-type retarder or a liquid crystal coating-type retarder, and may include a λ/2 retarder and/or a λ/4 retarder. The polarizer may also include a film-type polarizer or a liquid crystal coating-type polarizer. The film-type polarizer may include a stretchable synthetic resin film, and the liquid crystal coating-type polarizer may include liquid crystals arranged in a certain arrangement. The retarder and the polarizer may further include a protective layer.

In an alternative embodiment, the optical functional layer 500 may include a destructive interference structure. The destructive interference structure may include a first reflective layer and a second reflective layer, which are disposed in different layers from each other. First reflected light and second reflected light respectively reflected by the first reflective layer and the second reflective layer may destructively interfere with each other, and thus, reflectance of external light may be reduced.

Although embodiments in which the display panel 10 includes the organic light-emitting diode OLED as the light-emitting device 200 are described above, the display panel 10 according to one or more embodiments is not limited thereto. In an alternative embodiment, the display panel 10 may include a display panel including an inorganic light-emitting diode, i.e., an inorganic light-emitting display panel. In another alternative embodiment, the display panel 10 may be a quantum dot light-emitting display panel.

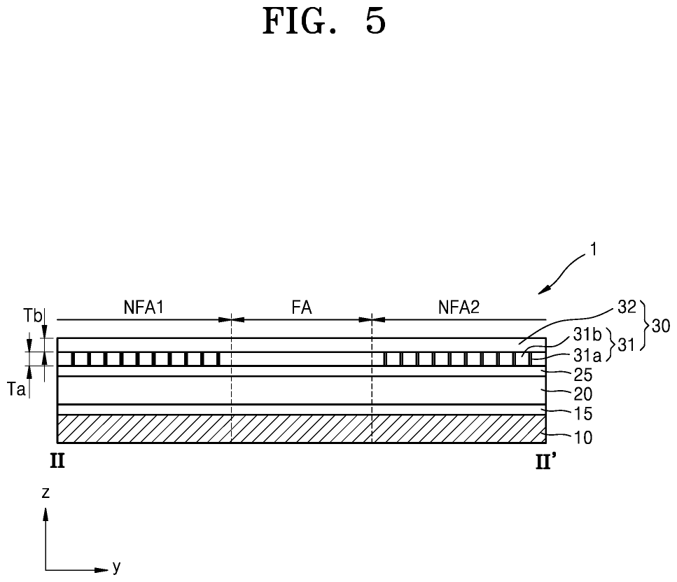

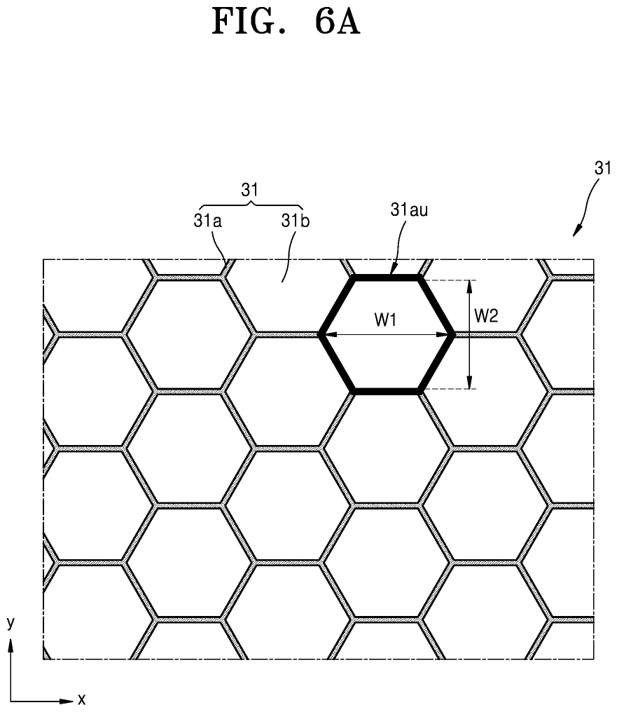

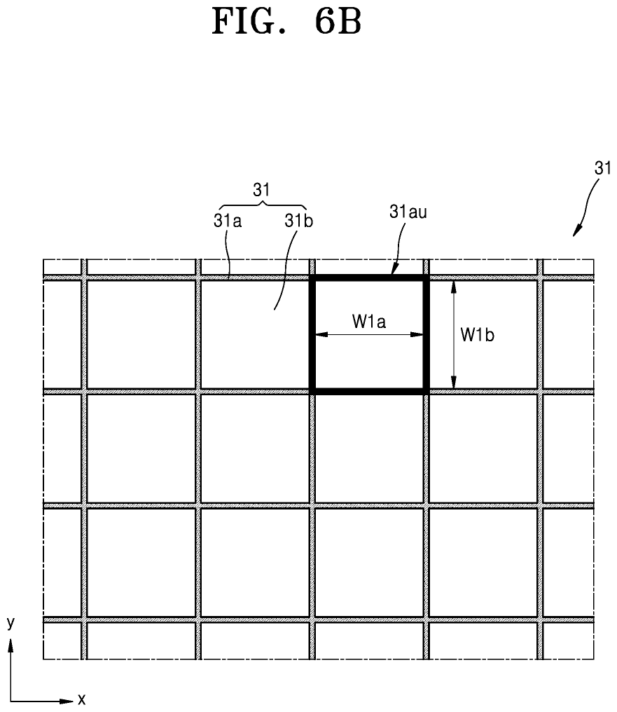

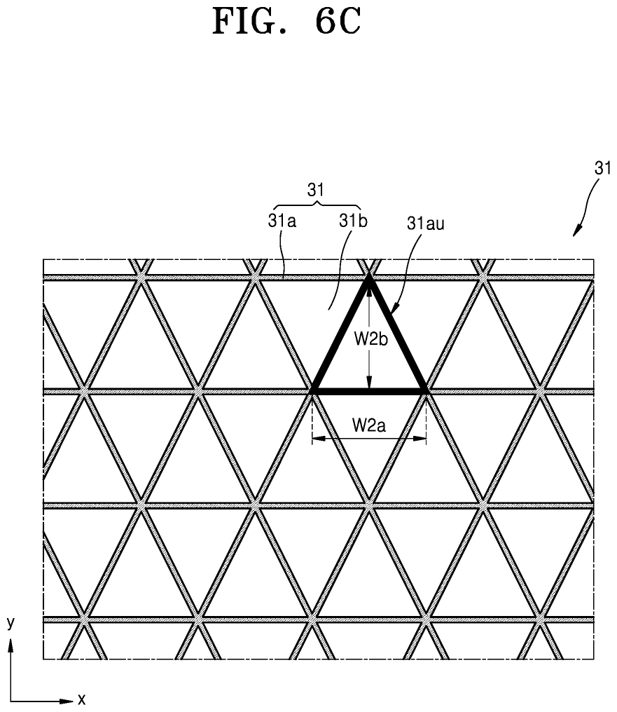

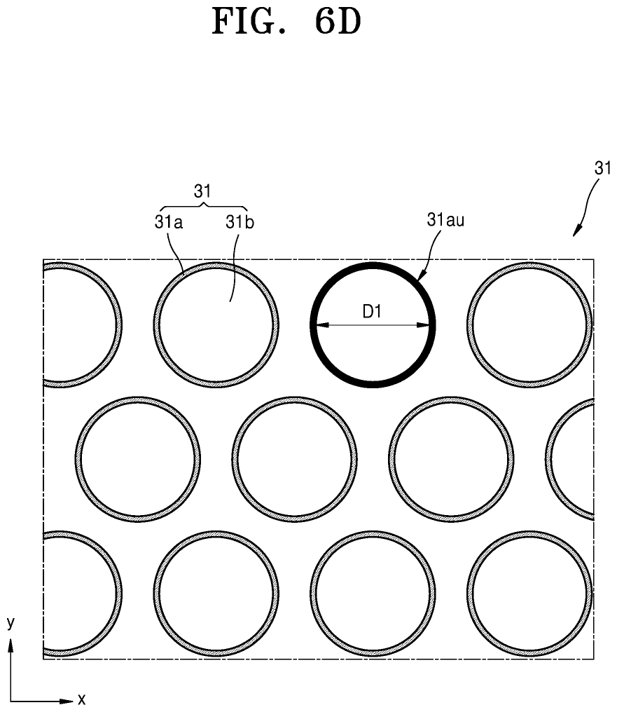

FIG. 5 is a schematic cross-sectional view of the display apparatus 1, taken along line II-II′ of FIG. 1A, according to an embodiment. FIGS. 6A to 6D are schematic plan views of a soft layer 31, according to various embodiments.

Referring to FIGS. 5 to 6D, an embodiment of the display apparatus 1 may include the display panel 10, a cover window 20 on the display panel 10, and a protective layer 30 on the cover window 20. The display apparatus 1 may further include a first adhesive layer 15 and a second adhesive layer 25.

In an embodiment, as described above, the display panel 10 may include the non-foldable areas NFA1 and NFA2 and the foldable area FA between the non-foldable areas NFA1 and NFA2. The foldable area FA may be between a plurality of non-foldable areas NFA1 and NFA2 to cause the non-foldable areas NFA1 and NFA2 to be spaced apart from each other. The protective layer 30 arranged over the display panel 10 may include the non-foldable areas NFA1 and NFA2 and the foldable area FA between the non-foldable areas NFA1 and NFA2.

The display panel 10 may provide an image. That is, a plurality of pixels PX (see FIG. 1A) may be arranged in the display panel 10 to form the display area DA (see FIG. 1A). The display panel 10 may have a stacked structure as described with reference to FIG. 4. That is, as shown in FIG. 4, the display panel 10 may include the substrate 100, the thin-film transistor TFT, the storage capacitor Cap, the light-emitting device 200, the encapsulation layer 300, the touch sensing layer 400, and the optical functional layer 500.

The cover window 20 may be arranged over the display panel 10. The cover window 20 may have high transmittance to transmit light emitted from the display panel 10. Also, the cover window 20 may have high strength and high hardness to protect the display apparatus 1 from external impact. The cover window 20 may include, e.g., glass or plastic. In an embodiment, the cover window 20 may include ultra-thin glass that has increased strength as a result of chemical strengthening or thermal strengthening.

The protective layer 30 may be arranged over the display panel 10. The protective layer 30 may be arranged over the cover window 20. The protective layer 30 may include a hard layer 32 and the soft layer 31 including a hard pattern 31a. The soft layer 31 may be a layer having relatively low stiffness, and the hard layer 32 may be a layer having relatively high stiffness. A thickness Ta of the soft layer 31 may be less than a thickness Tb of the hard layer 32.

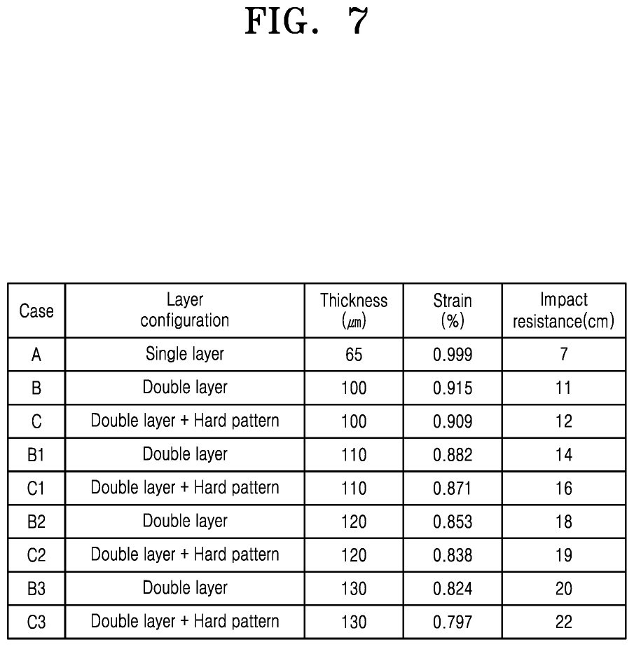

In such an embodiment where the protective layer 30 has a double layer structure including the hard layer 32 and the soft layer 31 including the hard pattern 31a, strain of the display panel 10 may decrease, and impact resistance of the display panel 10 may be improved as shown in FIG. 7.

The soft layer 31 may be arranged over the cover window 20. The soft layer 31 may be disposed on the second adhesive layer 25. The soft layer 31 may be between the cover window 20 and the hard layer 32.

The soft layer 31 may include the hard pattern 31a and a first material 31b. The first material 31b may be arranged across the foldable area FA and the non-foldable areas NFA1 and NFA2. The first material 31b may fill an empty space inside the hard pattern 31a in the non-foldable areas NFA1 and NFA2. The first material 31b may disposed in a space defined by the hard pattern 31a to fill an empty space inside the hard pattern 31a, i.e., an empty space defined in a layer defined by (or corresponding to) the hard pattern 31a. The hard pattern 31a may be arranged in an area overlapping each of the non-foldable areas NFA1 and NFA2 in a third direction (z-axis direction) and may not overlap the foldable area FA.

The hard pattern 31a may be a support pattern that prevents the hard layer 32 from sagging due to external impact. The hard pattern 31a is arranged only in the non-foldable areas NFA1 and NFA2 and not in the foldable area FA, and thus, the strain of the display panel 10 occurring in the foldable area FA during folding may be substantially reduced. The hard pattern 31a may be, e.g., a transparent resin. The hard pattern 31a may be, e.g., a resin for an imprinting process. The hard pattern 31a may be, e.g., an ultraviolet (UV) curable resin. The hard pattern 31a may include a material different from a second material included in the hard layer 32.

The hard pattern 31a may have relatively higher stiffness than the first material 31b. A modulus of the hard pattern 31a may be greater than a modulus of the first material 31b. In an embodiment, for example, the hard pattern 31a may have a modulus in a similar range to that of the second material included in the hard layer 32. In an embodiment, for example, the modulus of the hard pattern 31a may be in a range of about 3 gigapascals (GPa) to about 6 GPa. In a case where the modulus of the hard pattern 31a is excessively less than that of the hard layer 32, e.g., less than 3 GPa, the hard layer 32 may not be effectively prevented from sagging due to external impact. In a case where the modulus of the hard pattern 31a is excessively greater than that of the hard layer 32, e.g., greater than 6 GPa, the strain of the display panel 10 increases and a force applied to the display panel 10 increases, and accordingly, the impact resistance of the display panel 10 may decrease. As used herein, the modulus may refer to a Young's modulus or an elastic modulus that defines a relationship between stress and strain of a material.

The hard pattern 31a may be a pattern having a structure in which a plurality of unit patterns 31au are repeatedly arranged. Each of the unit patterns 31au of the hard pattern 31a may have various shapes according to embodiments. FIGS. 6A to 6D show various shapes of the soft layer 31 on an x-y plane when viewed from a vertical direction (z-direction) of a substrate of the display panel 10. In embodiments, as shown in FIGS. 6A to 6D, each of the unit patterns 31au of the hard pattern 31a may have, in a plan view, at least one of a honeycomb shape (see FIG. 6A), a rectangular shape (see FIG. 6B), a triangular shape (see FIG. 6C, or a circular shape (see FIG. 6D). In an embodiment, as shown in FIG. 5, each of the unit patterns 31au of the hard pattern 31a may a columnar shape having substantially a same height as the first material 31b. In an embodiment, for example, each of the unit patterns 31au of the hard pattern 31a may have at least one selected from a triangular prism shape, a quadrangular prism shape, a hexagonal prism shape, and a cylindrical shape. However, the illustrated shapes of a unit pattern 31au are only examples, and the shape of the unit pattern 31au may be variously changed in a range that satisfies ranges of first widths W1, W1a, and W1b and second widths W2, W2a, and W2b, which are described below.

As shown in FIGS. 6A to 6C, each of the unit patterns 31au of the hard pattern 31a may have the first widths W1, W1a, and W1b in a first direction (x-axis direction) and may have the second widths W2, W2a, and W2b in a second direction (y-axis direction). Each of the first widths W1, W1a, and W1b may be, e.g., in a range of about 100 micrometers (μm) to about 300 μm. Each of the second widths W2, W2a, and W2b may be, e.g., in a range of about 100 μm to about 300 μm.

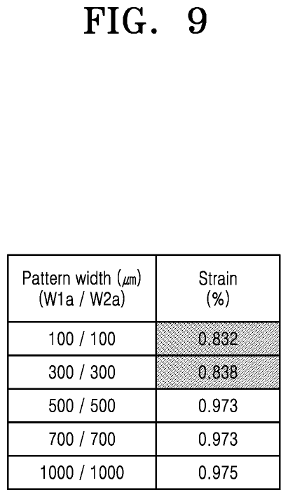

As shown in FIG. 9, when the first widths W1, W1a, and W1b and the second widths W2, W2a, and W2b of the unit pattern 31au are equal to or less than about 300 μm, the strain of the display panel 10 is small, and thus, the impact resistance of the display panel 10 may be effectively improved. In a case where the first widths W1, W1a, and W1b and the second widths W2, W2a, and W2b of the unit pattern 31au are greater than about 300 μm, the strain of the display panel 10 increases, and thus, the impact resistance of the display panel 10 may decrease. In a case where the first widths W1, W1a, and W1b and the second widths W2, W2a, and W2b of the unit pattern 31au are less than about 100 μm, it may be difficult to form the unit pattern 31au.

In an embodiment, the first widths W1, W1a, and W1b of the unit pattern 31au may be substantially the same as the second widths W2, W2a, and W2b of the unit pattern 31au, but are not limited thereto. In an alternative embodiment, the first widths W1, W1a, and W1b of the unit pattern 31au may be different from the second widths W2, W2a, and W2b of the unit pattern 31au.

In an embodiment, as shown in FIG. 6D, where the unit pattern 31au of the hard pattern 31a has a circular shape, a diameter D1 of the unit pattern 31au may be, e.g., in a range of about 100 μm to about 300 μm. In an embodiment, where the unit pattern 31au of the hard pattern 31a has an elliptical shape, a length of a long axis of the unit pattern 31au may be in a range of about 100 μm to about 300 μm, and a length of a short axis of the unit pattern 31au may be in a range of about 100 μm to about 300 μm.

The first material 31b may disperse external impact applied to the protective layer 30. The first material 31b may disperse external impact transmitted from the hard layer 32 and the hard pattern 31a. The first material 31b may be, e.g., a transparent resin.

The first material 31b may be, e.g., a resin for an imprinting process. The first material 31b may be, e.g., a UV curable resin.

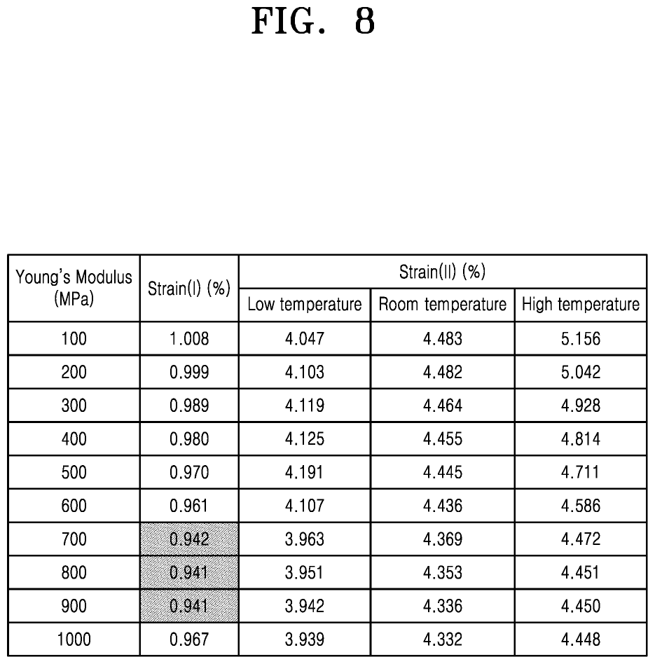

The first material 31b may have relatively less stiffness than the hard pattern 31a and the hard layer 32. A modulus of the first material 31b may be less than the modulus of the hard pattern 31a. The modulus of the first material 31b may be less than a modulus of the hard layer 32. The first material 31b may have a modulus in a range of about 700 megapascals (MP)a to about 900 MPa. As shown in FIG. 8, the impact resistance of the display panel 10 may be effectively improved when the first material 31b has a modulus in a range of about 700 MPa to about 900 MPa. In a case where the first material 31b has a modulus of less than 700 MPa or has a modulus of greater than 900 MPa, the strain of the display panel 10 may be greater than a case where the first material 31b has a modulus in a range of about 700 MPa to about 900 MPa, and thus, the impact resistance of the display panel 10 may decrease.

The hard layer 32 may be disposed on the soft layer 31. The hard layer 32 may be disposed on the hard pattern 31a and the first material 31b of the soft layer 31. The hard layer 32 may be arranged across the foldable area FA and the non-foldable areas NFA1 and NFA2.

The hard layer 32 may include the second material having higher stiffness than the first material 31b of the soft layer 31. In an embodiment, for example, the hard layer 32 may include a transparent polymer film. In an embodiment, for example, the hard layer 32 may include at least one selected from PET, PI, polyethersulfone (PS), polyacrylate (PAR), PEI, PEN, PPS, and PC. That is, the second material of the hard layer 32 may be, e.g., a transparent polymer film. In an embodiment, for example, the second material of the hard layer 32 may include, e.g., at least one selected from PET, PI, PS, PAR, PEI, PEN, PPS, and PC. The second material of the hard layer 32 may be, e.g., a polymer film having a modulus in a range of about 3 GPa to about 6 GPa.

The first adhesive layer 15 may be disposed on the display panel 10. The first adhesive layer 15 may be between the display panel 10 and the cover window 20. The second adhesive layer 25 may be disposed on the cover window 20. The second adhesive layer 25 may be between the cover window 20 and the protective layer 30. Each of the first adhesive layer 15 and the second adhesive layer 25 may be, e.g., an optical clear adhesive (OCA), an optical clear resin (OCR), or a pressure-sensitive adhesive (PSA).

FIG. 7 is a table showing strain and impact resistance of a display panel according to a layer configuration of a protective layer in a pen drop experiment. An impact resistance index is the maximum drop height of a pen at which the pen is not damaged during a pen drop experiment.

FIG. 7 shows strain and impact resistance according to a thickness in each of a case (Case A) in which the protective layer 30 described above with reference to FIG. 5 is a single layer, cases (Case B, Case B1, Case B2, and Case B3) in which the protective layer 30 is a double layer including the hard layer 32 and the soft layer 31 not including the hard pattern 31a, and cases (Case C, Case C1, Case C2, and Case C3) in which the protective layer 30 is a double layer including the hard layer 32 and the soft layer 31 including the hard pattern 31a, in the non-foldable areas NFA1 and NFA2.

It may be confirmed that, compared to a case (Case A) in which a protective layer is a single hard layer having a thickness of 65 μm, the strain is reduced from 0.999% to 0.915% in a case (Case B) in which the protective layer is a double layer including a soft layer and a hard layer and having a thickness of 100 μm. Also, it may be confirmed that, compared to the case (Case A) in which the protective layer is a single hard layer having a thickness of 65 μm, the impact resistance is improved from 7 cm to 11 cm in the case (Case B) in which the protective layer is a double layer including a soft layer and a hard layer and having a thickness of 100 μm.

It may be confirmed that, in a protective layer including a double layer having a thickness of 100 μm, compared to the case (Case B) in which the protective layer is a double layer including a soft layer not including a hard pattern, the strain is reduced from 0.915% to 0.909% in a case (Case C) in which the protective layer is a double layer including a soft layer including a hard pattern. Also, it may be confirmed that, in the protective layer including a double layer having a thickness of 100 μm, compared to the case (Case B) in which the protective layer is a double layer including a soft layer not including a hard pattern, the impact resistance is improved from 11 cm to 12 cm in the case (Case C) in which the protective layer is a double layer including a soft layer including a hard pattern.

It may be confirmed that, in a protective layer including a double layer having a thickness of 110 μm, compared to a case (Case B1) in which the protective layer is a double layer including a soft layer not including a hard pattern, the strain is reduced from 0.882% to 0.871% in a case (Case C1) in which the protective layer is a double layer including a soft layer including a hard pattern. Also, it may be confirmed that, in the protective layer including a double layer having a thickness of 110 μm, compared to the case (Case B1) in which the protective layer is a double layer including a soft layer not including a hard pattern, the impact resistance is improved from 14 cm to 16 cm in the case (Case C1) in which the protective layer is a double layer including a soft layer including a hard pattern.

It may be confirmed that, in a protective layer including a double layer having a thickness of 120 μm, compared to a case (Case B2) in which the protective layer is a double layer including a soft layer not including a hard pattern, the strain is reduced from 0.853% to 0.838% in a case (Case C2) in which the protective layer is a double layer including a soft layer including a hard pattern. Also, it may be confirmed that, in the protective layer including a double layer having a thickness of 120 μm, compared to the case (Case B2) in which the protective layer is a double layer including a soft layer not including a hard pattern, the impact resistance is improved from 18 cm to 19 cm in the case (Case C2) in which the protective layer is a double layer including a soft layer including a hard pattern.

It may be confirmed that, in a protective layer including a double layer having a thickness of 130 μm, compared to a case (Case B3) in which the protective layer is a double layer including a soft layer not including a hard pattern, the strain is reduced from 0.824% to 0.797% in a case (Case C3) in which the protective layer is a double layer including a soft layer including a hard pattern. Also, it may be confirmed that, in the protective layer including a double layer having a thickness of 130 μm, compared to the case (Case B3) in which the protective layer is a double layer including a soft layer not including a hard pattern, the impact resistance is improved from 20 cm to 22 cm in the case (Case C3) in which the protective layer is a double layer including a soft layer including a hard pattern.

As described above, it may be confirmed that the impact resistance of the display panel is most improved in case where the protective layer is a double layer including a hard layer and a soft layer including a hard pattern.

FIG. 8 is a table showing strain of a display panel according to a modulus of a material included in a soft layer. In detail, FIG. 8 shows strain (I) and strain (II) according to a modulus of the first material 31b of the soft layer 31 described above with reference to FIG. 5. The strain (I) is strain of the display panel due to external impact, and the strain (II) is strain of the display panel due to a folding operation of the display panel.

Referring to FIG. 8, it may be confirmed that the strain (I) of the display panel is 1.008 when the modulus is 100 MPa, the strain (I) of the display panel is 0.999 when the modulus is 200 MPa, the strain (I) of the display panel is 0.989 when the modulus is 300 MPa, the strain (I) of the display panel is 0.980 when the modulus is 400 MPa, the strain (I) of the display panel is 0.970 when the modulus is 500 MPa, and the strain (I) of the display panel is 0.961 when the modulus is 600 MPa. Also, it may be confirmed that the strain (I) of the display panel is 0.942 when the modulus is 700 MPa, the strain (I) of the display panel is 0.941 when the modulus is 800 MPa, and the strain (I) of the display panel is 0.941 when the modulus is 900 MPa. In addition, it may be confirmed that the strain (I) of the display panel is 0.967 when the modulus is 1000 MPa.

As described above, it may be confirmed that the strain (I) is sequentially reduced when the modulus of the first material 31b (see FIG. 5) of the soft layer 31 (see FIG. 5) is increased from 100 MPa to 700 MPa, and increased again at a modulus of 1000 MPa exceeding 900 MPa. As the strain is reduced, the magnitude of a force applied to the display panel is reduced, and thus, the impact resistance may be improved. Accordingly, in a case where a modulus of a first material of a soft layer is formed in a range of about 700 MPa to about 900 MPa, the impact resistance may be improved so that the strain (I) is in a range of about 0.942% to about 0.941%.

It may be confirmed that the strain (II) occurring when the display apparatus is folded is increased when the modulus of the first material 31b (see FIG. 5) of the soft layer 31 (see FIG. 5) is increased from 100 MPa to 400 MPa, and sequentially reduced when the modulus is increased from 100 MPa to 1000 MPa at a low temperature. Also, it may be confirmed that the strain (II) is sequentially reduced when the modulus of the first material 31b (see FIG. 5) of the soft layer 31 (see FIG. 5) is increased from 100 MPa to 1000 MPa at a room temperature. It may be confirmed that the strain (II) is sequentially reduced when the modulus of the first material 31b (see FIG. 5) of the soft layer 31 (see FIG. 5) is increased from 100 MPa to 1000 MPa at a high temperature.

In comprehensive consideration of the strain (I) and the strain (II), the impact resistance may be most improved in a case where the modulus of the first material 31b of the soft layer 31 is in a range of about 700 MPa to about 900 MPa.

FIG. 9 is a table showing strain of a display panel according to a first width W1a and a second width W2a of a unit pattern constituting a hard pattern included in a soft layer of a protective layer. In detail, FIG. 9 shows data in an embodiment in which the unit pattern of the hard pattern has a rectangular shape. The first width W1a is a width in a first direction, e.g., an x-axis direction, and the second width W2a is a width in a second direction, e.g., a y-axis direction, the second direction crossing the first direction.

Referring to FIG. 9, it may be confirmed that the strain is 0.832% when each of the first width W1a and the second width W2a of the unit pattern is 100 μm, the strain is 0.838% when each of the first width W1a and the second width W2a of the unit pattern is 300 μm, the strain is 0.973% when each of the first width W1a and the second width W2a of the unit pattern is 500 μm, the strain is 0.973% when each of the first width W1a and the second width W2a of the unit pattern is 700 μm, and the strain is 0.975% when each of the first width W1a and the second width W2a of the unit pattern is 1000 μm.

As described above, because the strain has a value of less than 0.9% when a width of one unit pattern is less than or equal to 300 μm, a width of the unit pattern of the hard pattern may be 300 μm or less.

According to one or more embodiments, a display apparatus includes a protective layer includes a soft layer including a hard pattern, and a hard layer disposed on the soft layer, such that the display apparatus having improved impact resistance may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a display panel including a foldable area, and a first non-foldable area and a second non-foldable area, wherein the foldable area is foldable about an axis extending in a first direction, and the first non-foldable area and the second non-foldable area are spaced apart from each other in a second direction crossing the first direction with the foldable area therebetween;
a cover window disposed on the display panel; and
a protective layer disposed on the cover window, wherein the protective layer includes a soft layer and a hard layer, the soft layer is on the cover window and includes a first material, and the hard layer is on the soft layer and includes a second material having a Young's modulus greater than a Young's modulus of the first material,
wherein the soft layer includes a hard pattern in a portion overlapping the first non-foldable area and the second non-foldable area, and
the hard pattern is not in a portion overlapping the foldable area.

2. The display apparatus of claim 1, wherein the first material has a Young's modulus less than a Young's modulus of the hard pattern.

3. The display apparatus of claim 1, wherein the Young's modulus of the first material is in a range of about 700 MPa to about 900 MPa.

4. The display apparatus of claim 1, wherein
the hard pattern includes a plurality of unit patterns,
each of the plurality of unit patterns of the hard pattern has a first width in the first direction and a second width in the second direction,
the first width is in a range of about 100 μm to about 300 μm, and
the second width is in a range of about 100 μm to about 300 μm.

5. The display apparatus of claim 4, wherein the first width and the second width are equal to each other.

6. The display apparatus of claim 4, wherein the first width and the second width are different from each other.

7. The display apparatus of claim 1, wherein a thickness of the soft layer is less than a thickness of the hard layer.

8. The display apparatus of claim 1, wherein
the hard pattern includes a plurality of unit patterns, and
each of the plurality of unit patterns has at least one selected from a honeycomb shape, a triangular shape, a rectangular shape and a circular shape.

9. The display apparatus of claim 1, wherein the hard pattern includes an ultraviolet curable resin.

10. The display apparatus of claim 1, wherein the first material includes an ultraviolet curable resin.

11. The display apparatus of claim 1, wherein the hard pattern includes a material different from the second material.

12. The display apparatus of claim 1, wherein the hard pattern has a Young's modulus in a range of about 3 GPa to about 6 GPa.

13. The display apparatus of claim 1, wherein the second material includes at least one selected from polyethylene terephthalate, polyimide, polyethersulfone, polyacrylate, polyetherimide, polyethylene naphthalate, polyethylene sulfide, and polycarbonate.

14. A display apparatus comprising:
a display panel including a foldable area, and a first non-foldable area and a second non-foldable area, wherein the foldable area is foldable about an axis extending in a first direction, and the first non-foldable area and the second non-foldable area are spaced apart from each other in a second direction crossing the first direction with the foldable area therebetween;
a cover window disposed on the display panel; and
a protective layer disposed on the cover window, wherein the protective layer includes a soft layer on the cover window and a hard layer on the soft layer,
wherein the soft layer includes a hard pattern and a first material,
the hard pattern is arranged to overlap the first non-foldable area and the second non-foldable area,
the first material has a Young's modulus in a range of about 700 MPa to about 900 MPa and disposed in a space defined by the hard pattern, and
the hard layer includes a second material having a Young's modulus greater than the Young's modulus of the first material.

15. The display apparatus of claim 14, wherein
the hard pattern is not in a portion of the soft layer overlapping the foldable area, and
the hard pattern has a Young's modulus greater than the Young's modulus of the first material.

16. The display apparatus of claim 14, wherein
the hard pattern includes a plurality of unit patterns,
each of the plurality of unit patterns has a first width in the first direction and a second width in the second direction crossing the first direction,
the first width is in a range of about 100 μm to about 300 μm, and
the second width is in a range of about 100 μm to about 300 μm.

17. The display apparatus of claim 14, wherein a thickness of the soft layer is less than a thickness of the hard layer.

18. The display apparatus of claim 14, wherein
the hard pattern includes a plurality of unit patterns, and
each of the plurality of unit patterns has at least one selected from a honeycomb shape, a triangular shape, a rectangular shape, and a circular shape.

19. The display apparatus of claim 14, wherein the hard pattern includes an ultraviolet curable resin.

20. The display apparatus of claim 14, wherein the first material includes an ultraviolet curable resin.
